(19) United States
(12) Patent Application Publication
(10) Pub. No.: US 2015/0195472 A1
(43) Pub. Date: Jul. 9, 2015

(54) SOLID-STATE IMAGING DEVICE

(71) Applicant: Panasonic Intellectual Property Management Co., Ltd., Osaka (JP)

(72) Inventor: Motonori ISHII, Osaka (JP)

(21) Appl. No.: 14/666,730

(22) Filed: Mar. 24, 2015

Related U.S. Application Data
(63) Continuation of application No. PCT/JP2013/002538, filed on Apr. 15, 2013.

(30) Foreign Application Priority Data
Sep. 27, 2012 (JP) 2012-214034

(51) Int. Cl. H04N 5/378

(52) U.S. Cl. CPC H04N 5/378

(57) ABSTRACT

A solid-state imaging device according to the present disclosure includes a pixel unit in which a plurality of pixels are disposed in a matrix. Each pixel includes a photoelectric conversion unit, an FD portion, an amplification transistor, a reset transistor, and a selection transistor. For each column, the pixel unit includes a power source line that is connected to a drain of the amplification transistor, a column signal line that is connected to a source of the selection transistor, a first feedback line that is connected to a drain of the reset transistor, a negative feedback circuit, and a positive feedback circuit. The negative feedback circuit negatively feeds a signal outputted to the column signal line back to the first feedback line, and the positive feedback circuit positively feeds the signal outputted to the column signal line back to the power source line.

### CROSS REFERENCE TO RELATED APPLICATIONS

This is a continuation application of PCT International Application No. PCT/JP2013/002538 filed on Apr. 15, 2013, designating the United States of America, which is based on and claims priority of Japanese Patent Application No. 2012-214034 filed on Sep. 27, 2012. The entire disclosures of the above-identified applications, including the specifications, drawings and claims are incorporated herein by reference in their entirety.

### FIELD

The present disclosure relates to a solid-state imaging device, and particularly to a stacked solid-state imaging device.

### BACKGROUND

Patent Literature (PTL) 1 discloses a stacked solid-state imaging device. In the stacked solid-state imaging device disclosed in PTL 1, noise is generated when a signal charge is reset. More specifically, in the case where a reset pulse is sharp when turned off, it is randomly determined whether a source or a drain of a reset transistor an electric charge on a channel moves to, so that kTC noise is generated. Also, the kTC noise is generated from capacitive coupling between a reset signal line and a pixel electrode, etc.

Furthermore, the stacked solid-state imaging device cannot completely cancel out the kTC noise even by using correlated double sampling. This is because, in the stacked solid-state imaging device, a semiconductor substrate and a photoelectric conversion unit provided above the semiconductor substrate are connected using a material having a high electric conductivity such as metal, making it difficult to completely transfer electric charges. Since a subsequent signal charge is added while the kTC noise still remains after resetting, a signal charge having the kTC noise superimposed thereon is read out. Thus, the solid-state imaging device disclosed in PTL 1 has a problem of increased kTC noise.

In order to reduce the kTC noise, a technique as disclosed in PTL 2 has been proposed.

FIG. 6 illustrates a unit pixel and a peripheral circuit thereof disclosed in PTL 2. Resetting a unit pixel 531 illustrated in this figure is started by turning on a selection transistor 543 and a reset transistor 535. A signal having an opposite phase of a difference between an output voltage from an amplification transistor 547 and a reference voltage VR of a column-shared feedback circuit 533 is fed back to a FD portion (a charge storage portion) 527 via the reset transistor 535, whereby the kTC noise generated in the reset transistor 535 is reduced.

### CITATION LIST

### Patent Literature

[PTL 1] Japanese Unexamined Patent Application Publication No. 55-120182
[PTL 2] U.S. Pat. No. 6,777,660

### SUMMARY

### Technical Problem

However, with the technique disclosed in PTL 2, no matter how much a gain of the column-shared negative feedback circuit 533 is raised, the kTC noise corresponding to a source-drain capacitance of the reset transistor 535 remains inevitably.

With the foregoing problem in mind, one non-limiting and explanatory embodiment provides a solid-state imaging device capable of reducing remaining kTC noise.

### Solution to Problem

In order to solve the problem described above, a solid-state imaging device according to one aspect of the present disclosure includes a semiconductor substrate; and a pixel unit including a plurality of pixels that are disposed in a matrix on the semiconductor substrate. Each of the plurality of pixels includes: a photoelectric conversion film that photoelectrically converts incident light to a signal charge; a pixel electrode that is disposed on a semiconductor substrate-side surface of the photoelectric conversion film; a transparent electrode that is disposed on a surface of the photoelectric conversion film, the surface of the photoelectric conversion film being opposite from the pixel electrode; a charge storage portion that is electrically connected to the pixel electrode and stores the signal charge; an amplification transistor that outputs a pixel signal corresponding to an amount of the signal charge; a reset transistor that resets an electric potential of the charge storage portion; and a selection transistor that determines timing at which the amplification transistor outputs the pixel signal. For each column of the plurality of pixels, the pixel unit includes: a power source line that is connected to one of a source and a drain of each of a plurality of the amplification transistors disposed in the each column; a column signal line that is connected to one of a source and a drain of each of a plurality of the selection transistors disposed in the each column; a first feedback line that is connected to one of a source and a drain of each of a plurality of the reset transistors disposed in the each column; a first amplification portion including an input terminal connected to the column signal line and an output terminal connected to the first feedback line; and a second amplification portion including an input terminal connected to the column signal line. The first amplification portion negatively feeds a signal outputted to the column signal line back to the first feedback line, and the second amplification portion positively feeds the signal outputted to the column signal line back to the power source line.

### Advantageous Effects

With the solid-state imaging device according to one aspect of the present disclosure, it becomes possible to reduce the kTC noise.

### BRIEF DESCRIPTION OF DRAWINGS

These and other objects, advantages and features of the invention will become apparent from the following description thereof taken in conjunction with the accompanying drawings that illustrate a specific embodiment of the present disclosure.

FIG. 1 is a block diagram illustrating an overall configuration of a solid-state imaging device according to an embodiment.

FIG. 2 is a structural sectional view illustrating three pixels in the solid-state imaging device according to an embodiment.

FIG. 3 is a circuit diagram illustrating a pixel and a control circuit in a solid-state imaging device according to Embodiment 1.

FIG. 4 is a timing chart illustrating how to drive the solid-state imaging device according to Embodiment 1.

FIG. 5 is a circuit diagram illustrating a pixel and a control circuit in a solid-state imaging device according to Embodiment 2.

FIG. 6 illustrates a unit pixel and a peripheral circuit hereof disclosed in PTL 2.

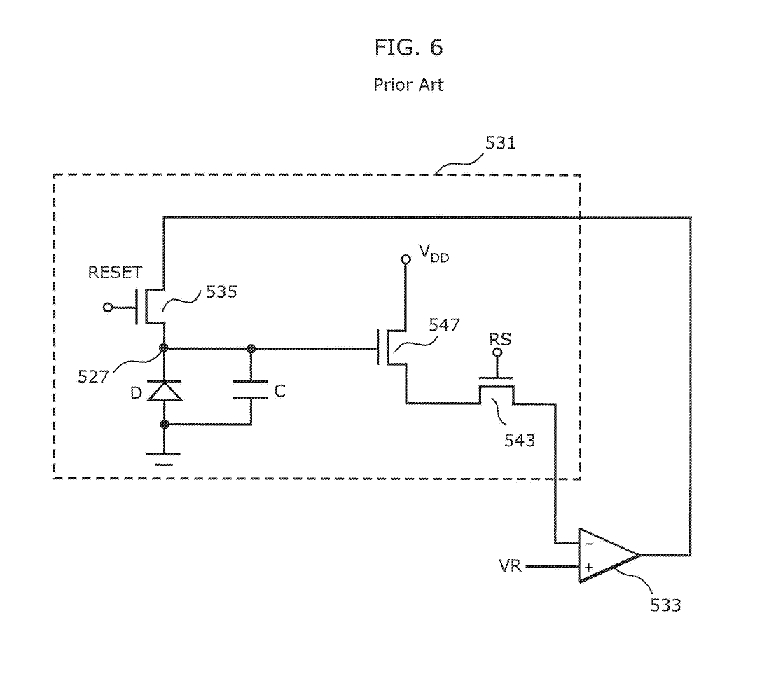

### DESCRIPTION OF EMBODIMENTS

The following is a description of a solid-state imaging device according to exemplary embodiments, with reference to the accompanying drawings. Incidentally, although the solid-state imaging device according to the present disclosure will be described by way of embodiments and drawings, such embodiments and drawings are provided for the purpose of illustration without any intention that the solid-state imaging device according to the present disclosure will be limited to them.

### Embodiment 1

Now, an overall configuration of a solid-state imaging device according to Embodiment 1 will be described.

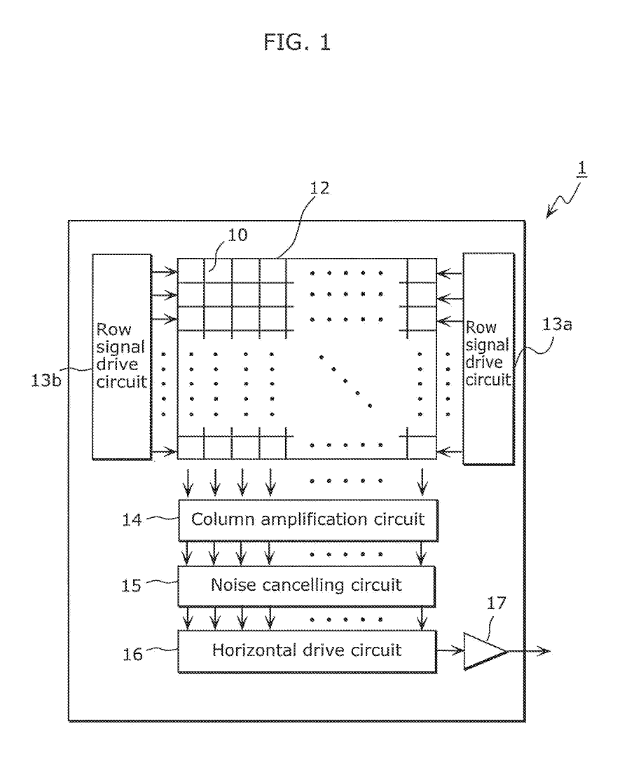

FIG. 1 is a block diagram illustrating the overall configuration of the solid-state imaging device according to the present embodiment. A solid-state imaging device 1 illustrated in this figure includes a pixel unit 12 in which a plurality of pixels 10 are arranged in a matrix, row signal drive circuits 13a and 13b, a column amplification circuit 14 arranged for each column, a noise cancelling circuit 15 such as a correlated double sampling (CDS) circuit arranged in each column, a horizontal drive circuit 16, and an output stage amplifier 17.

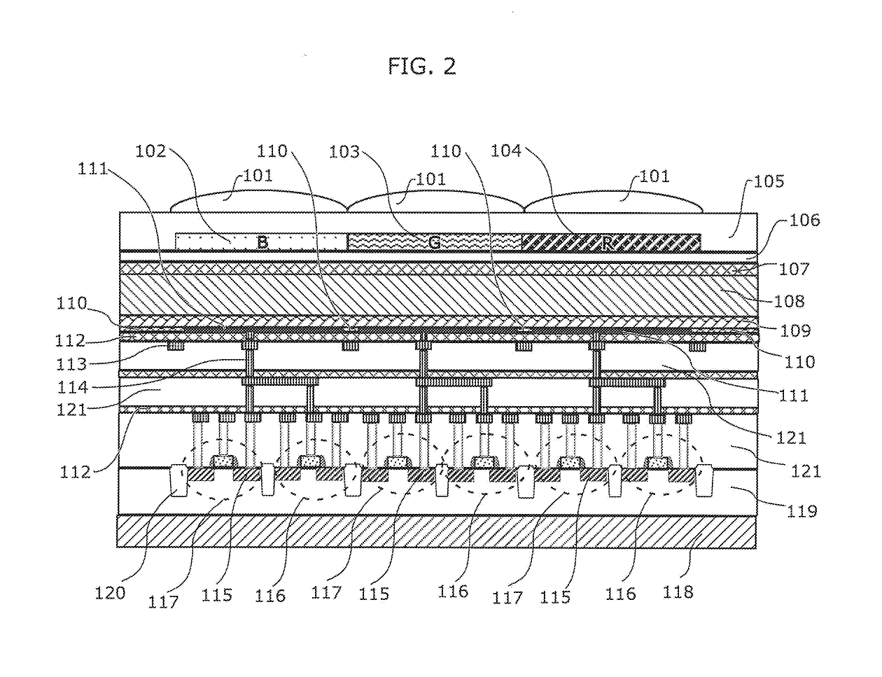

FIG. 2 is a structural sectional view illustrating three pixels in the solid-state imaging device according to the present embodiment. It should be noted that, in an actual solid-state imaging device, the pixel unit 12 includes, for example, ten million pixels arranged in a matrix. As illustrated in FIG. 2, the solid-state imaging device 1 includes microlenses 101, a red color filter 104, a green color filter 103, a blue color filter 102, a protective film 105, a flattening film 106, an upper electrode 107, a photoelectric conversion film 108, an electron blocking layer 109, inter-electrode insulating films 110, lower electrodes 111, inter-wiring insulating films 112, feeder layers 113, wiring layers 114, a substrate 118, a well 119, shallow trench isolation (STI) regions 120, and an inter-layer insulating layer 121.

The substrate 118 is a semiconductor substrate, for example, a silicon substrate. A p-type well 119 is formed on the substrate 118. Furthermore, the STI region 120 for electrically isolating elements is formed in the well 119. The STI region 120 may be formed of SiO₂ or an isolation region highly doped with p-type impurities. In the well 119, an FD portion (charge storage portion) 115, an amplification transistor 116, a reset transistor 117, and a selection transistor that is not shown in the figure but formed in the same pixel are provided as a signal read-out circuit. Incidentally, the conductivity type of the well 119 is set to the p type here but may be an n type.

In order to efficiently collect incident light, the microlens 101 is disposed in each of the pixels 10 on an outermost surface of the solid-state imaging device 1.

The red color filter 104, the green color filter 103, and the blue color filter 102 are provided for capturing a color image. Also, the red color filter 104, the green color filter 103, and the blue color filter 102 are disposed immediately below the respective microlenses 101 and inside the protective film 105. In order to form a group of the microlenses 101 and the color filters without any focusing and color unevenness over the ten million pixels, these optical elements are disposed on the flattening film 106. The flattening film 106 is formed of, for example, SiN.

The upper electrode 107 is disposed over an entire surface of the pixel unit 12 in such a manner as to be located below the flattening film 106 and on a surface of the photoelectric conversion film 108 opposite from the lower electrode 111. This upper electrode 107 is a transparent electrode that transmits visible light. For example, the upper electrode 107 is formed of an indium tin oxide (ITO).

The photoelectric conversion film 108 converts light into signal charges. More specifically, the photoelectric conversion film 108 is provided below the upper electrode 107 and contains organic molecules having a high light absorptivity. Also, the photoelectric conversion film 108 has a thickness of, for example, about 500 nm. Furthermore, the photoelectric conversion film 108 is formed by, for example, vacuum deposition. The above-noted organic molecules have a high light absorptivity over an entire visible light range at wavelengths ranging from about 400 nm to about 700 nm.

The electron blocking layer 109 is provided below the photoelectric conversion film 108, conducts positive holes generated by the photoelectric conversion of the incident light, and blocks electrons from the lower electrode 111. This electron blocking layer 109 is disposed on the inter-electrode insulating film 110 and the lower electrode 111 that have high flatness. The electron blocking layer 109 is formed of, for example, an organic material.

The plurality of lower electrodes 111 are pixel electrodes that are arranged in a matrix above the substrate 118 and on a surface of the photoelectric conversion film 108 facing the substrate 118. Also, the plurality of lower electrodes 111 are electrically isolated from each other at intervals of 0.2 μm. More specifically, each of the lower electrodes 111 is disposed between the inter-electrode insulating films 110, and collects the positive holes generated in the photoelectric conversion film 108. Such lower electrodes 111 are formed of, for example, TiN. Moreover, the lower electrodes 111 are disposed on the inter-wiring insulating film 112 that is flattened and has a thickness of about 100 nm.

The feeder layer 113 is provided below the inter-electrode insulating film 110 and immediately under the inter-wiring insulating film 112. This feeder layer 113 is formed of, for example, Cu. More specifically, the feeder layer 113 is disposed between the adjacent lower electrodes 111 and between the lower electrode 111 and the substrate 118. Also, the feeder layer 113 can be supplied with an electric potential independent of that of the lower electrode 111. More specifically, at the time of exposure operation in which the photoelectric conversion film 108 performs the photoelectric conversion and at the time of read-out operation in which the signal read-out circuit generates a pixel signal corresponding to a signal charge amount, the feeder layer 113 is supplied with an electric potential for excluding signal charges. For example, when the signal charges are positive holes, a positive voltage is applied. With this configuration, it is possible to prevent the positive holes from entering each pixel from adjacent pixels. It should be noted that the voltage application to the feeder layer 113 is controlled by, for example, a control unit (not shown) included in the solid-state imaging device 1.

The feeder layer 113 is connected to the wiring layer 114. Furthermore, the wiring layer 114 is connected to the FD portion 115 of the signal read-out circuit and a gate terminal of the amplification transistor 116. The FD portion 115 is a charge storage portion that is electrically connected to the lower electrode 111 and stores the signal charges from the photoelectric conversion film 108, and also serves as one of a source and a drain of the reset transistor 117. The signal read-out circuit formed in the well 119 senses variations in an electric current or a voltage occurring in each of the plurality of lower electrodes 111, thereby generating a pixel signal corresponding to a signal charge amount. More specifically, the amplification transistor 116 amplifies the variations in the current or voltage occurring in the lower electrode 111, thereby generating the pixel signal corresponding to the signal charge amount.

Furthermore, a gate terminal of the reset transistor 117 is connected to a reset transistor control line. The potential of the reset transistor control line is used to control on and off of the reset transistor 117. For example, when the potential of the reset transistor control line is at a High level, the reset transistor 117 is turned on. Also, when the potential of the reset transistor control line is at a Low level, the reset transistor 117 is turned off.

Furthermore, a gate terminal of the selection transistor is connected to a selection transistor control line. The potential of the selection transistor control line is used to control on and off of the selection transistor. For example, when the potential of the selection transistor control line is at a High level, the selection transistor is turned on. Also, when the potential of the selection transistor control line is at a Low level, the selection transistor is turned off.

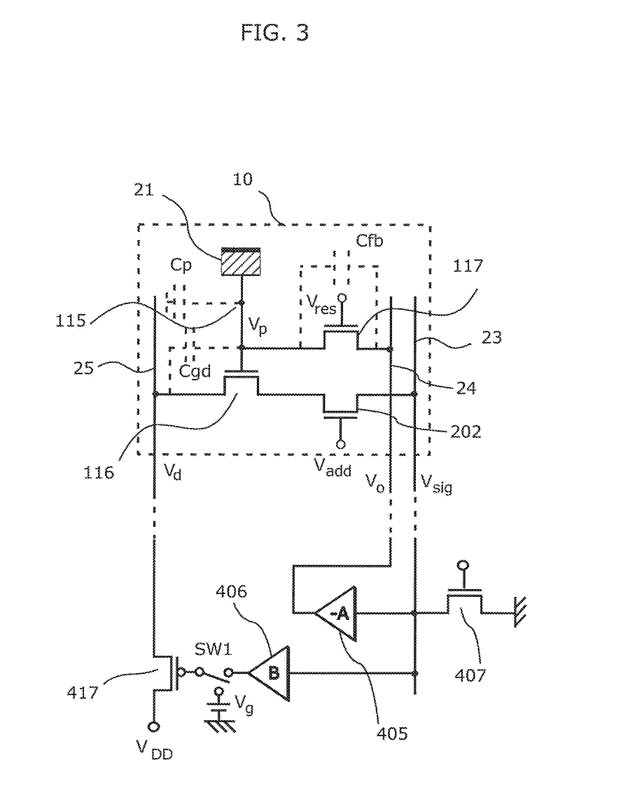

FIG. 3 is a circuit diagram illustrating a pixel and a control circuit in the solid-state imaging device according to Embodiment 1. More specifically, FIG. 3 illustrates an example of a circuit of the pixel 10 in the mth row and nth column in the pixel unit 12 and a control circuit thereof in the present embodiment, where m and n are natural numbers. The pixel 10 includes a photoelectric conversion unit 21, the reset transistor 117, the amplification transistor 116, a selection transistor 202, the FD portion 115, and a column signal line 23 that is provided for each column of the pixel unit 12.

Furthermore, a column-shared circuit provided for each column in the pixel unit 12 includes a negative feedback circuit 405, a positive feedback circuit 406, a first current source transistor 407, a second current source transistor 417, a switch SW1, a first feedback line 24 serving as an output line of the negative feedback circuit 405, and a power source line 25 whose potential is controlled by an output of the positive feedback circuit 406.

The negative feedback circuit 405 is a first amplification portion whose input terminal is connected to the column signal line and whose output terminal is connected to the first feedback line 24, and negatively feeds a signal outputted to the column signal line 23 back to the first feedback line 24.

When a control signal S1 of the switch SW1 is at a High level, an output of the positive feedback circuit 406 is connected to a gate of the second current source transistor 417 via the switch SW1. When the control signal S1 is at a Low level, the switch SW1 is connected to a constant voltage Vg. The pixels 10 that are arranged in the same column are connected to the same column-shared circuit. Furthermore, by turning on only the selection transistors 202 in the pixels 10 arranged in one row, one column-shared circuit is connected to only one pixel 10.

The positive feedback circuit 406, the switch SW1 and a constant voltage source for supplying the constant voltage Vg form a second amplification portion whose input terminal is connected to the column signal line 23. This second amplification portion positively feeds a signal outputted to the column signal line 23 back to the power source line 25.

The positive feedback circuit 406 is an amplification circuit whose input terminal is connected to the column signal line 23 and that has a negative gain. The second current source transistor 417 is a MOS transistor having its gate connectable to an output terminal of the positive feedback circuit 406 via the switch SW1, one of its source and drain connected to the power source line 25, and the other of its source and drain connected to a power source voltage VDD.

It should be noted that, in FIG. 3, the reset transistor 117, the amplification transistor 116, and the selection transistor 202 in the pixel 10 are formed of p channel-type MOS transistors. Also, the first current source transistor 407 and the second current source transistor 417 in the column-shared circuit are formed of n channel-type MOS transistors. The channel type of each of the transistors may be reversed.

Now, a basic method for driving the solid-state imaging device according to Embodiment 1 will be described. Since the control signal S1 is at a Low level, in other words, the switch SW1 is connected to the constant voltage Vg, the power source line 25 is supplied with the power source voltage VDD. First, a pixel signal Vsig corresponding to the amount of the signal charges generated in the photoelectric conversion unit 21 is outputted to the column signal line 23 via the amplification transistor 116 and the selection transistor 202. At this time, the reset transistor 117 is off, and the selection transistor 202 in a row to be read out is on.

Then, by turning on the reset transistor 117, the potential of the FD portion 115 is reset. Thereafter, when the reset transistor 117 is turned off, the kTC noise is generated. At this time, using the negative feedback circuit 405, a signal having an opposite phase from the output signal to the column signal line 23 is outputted to the FD portion 115 via the first feedback line 24. During this period, the reset transistor 117 is gradually turned off, thereby reducing the kTC noise generated in the reset transistor 117.

The charge amount of the kTC noise remaining in the FD portion 115 at the instant the resetting is completed can be expressed by Formula 1 when a transfer function of a negative feedback system is derived and analyzed while ignoring a source-drain capacitance Cfb of the reset transistor 117.

$$\sqrt{\frac{kTCp}{( A + 1 )}} \qquad [ Formula 1 ]$$

In Formula 1, k indicates Boltzmann constant, T indicates an absolute temperature, Cp indicates a capacitance of the FD portion 115, and A indicates a voltage gain of the negative feedback circuit 405, which takes a positive value.

However, in reality, the source-drain capacitance Cfb of the reset transistor 117 cannot be ignored. In other words, on the charge amount of the kTC noise expressed by Formula 1, noise corresponding to the source-drain capacitance Cfb of the reset transistor 117 is further superimposed and applied to the FD portion 115. This is because, since a voltage Vo of the first feedback line 24 of the negative feedback circuit 405 varies from the time when the resetting is completed by the time when the reset voltage is read out, the variation in the voltage Vo is superimposed and applied via the capacitance Cfb to the FD portion 115. More specifically, if the control signal of the reset transistor 117 continues lowering even after the completion of resetting, parasitic capacitance of the gate of the reset transistor 117 and the gate of the amplification transistor 116 causes a gate voltage of the amplification transistor 116 to vary considerably. At this time, an output voltage from the amplification transistor 116 exceeds an input dynamic range of the negative feedback circuit 405, so that the voltage Vo of the first feedback line 24 has a certain constant value that does not correlate with the gate voltage of the amplification transistor 116. This phenomenon can be solved if the input dynamic range of the negative feedback circuit 405 is expanded.

However, when a pixel signal Vsig is read out again following the read-out of the reset signal and the exposure, an operation of the pixel 10 in another row is interposed, so that the voltage Vo of the first feedback line 24 varies again. In order to prevent the noise corresponding to the source-drain capacitance Cfb of the reset transistor 117 from being superimposed and applied further to the FD portion 115, the voltage Vo of the first feedback line 24 at the time of reading out the pixel signal Vsig has to be equal to the voltage Vo of the first feedback line 24 at the time of resetting in the immediately preceding frame. However, it is not realistic in terms of costs to arrange as many memories as the rows for the purpose of storing the voltage Vo of the first feedback line 24 at the time of resetting in the individual pixels. Thus, for example, a method is conceivable of setting a voltage gain A of the negative feedback circuit 405 to 0 so as to fix the voltage Vo of the first feedback line 24 at the time of reading out the pixel signal Vsig.

In both of a pixel signal read-out period and a reset signal read-out period, the noise that corresponds to Formula 1 and is superimposed and applied to the first feedback line 24 is canceled out by setting the voltage Vo of the first feedback line 24 to a constant voltage. Accordingly, a standard deviation of a variation amount of the voltage Vo of the first feedback line 24 at this time corresponds to the noise originally superimposed and applied to the first feedback line 24 and is thus expressed by Formula 2.

$$A \sqrt{\frac{kT}{( A + 1 ) Cp}} \qquad [ Formula 2 ]$$

This voltage variation is superimposed and applied to the FD portion 115 via the capacitance Cfb. The superimposed voltage is expressed by Formula 3.

$$A \sqrt{\frac{kT}{( A + 1 ) Cp}} \frac{Cp}{Cp + Cfb} \qquad [ Formula 3 ]$$

A polarity of the voltage expressed by Formula 3 coincides with a polarity of the voltage of the noise expressed by Formula 1. Accordingly, the charge amount of the kTC noise superimposed and applied to the FD portion 115 can be expressed by Formula 4. Incidentally, since the calculation has been performed without including the capacitance Cfb when deriving Formula 1, which is a fundamental formula of Formula 4, Formula 4 produces an approximate value.

$$( 1 + A \frac{Cfb}{Cp + Cfb} ) \sqrt{\frac{kTCp}{( A + 1 )}} \qquad [ Formula 4 ]$$

From Formula 4, it is understood that the noise increases when the capacitance Cfb is significant with respect to Cp.

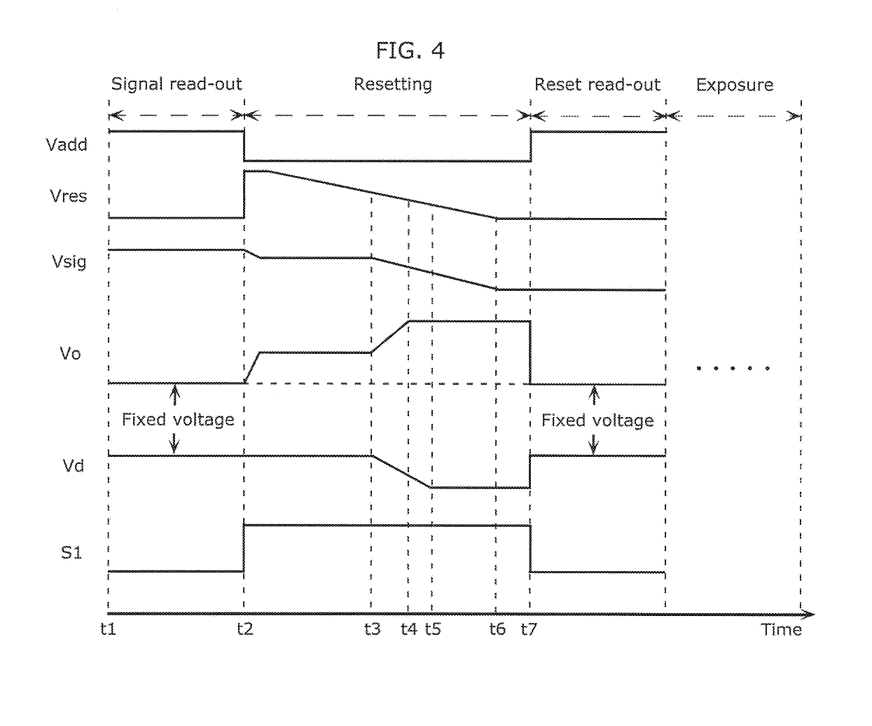

FIG. 4 is a timing chart illustrating how to drive the solid-state imaging device according to Embodiment 1. More specifically, FIG. 4 is a timing chart illustrating a method for driving pixels in the mth row including the pixel 10 illustrated in FIG. 3 and a control circuit thereof. This driving method can suppress the above-described kTC noise of the FD portion 115.

At time t1, a control signal Vadd of the selection transistor 202 is turned on, and a control signal Vres of the reset transistor 117 is turned off. Thus, a pixel signal Vsig corresponding to the signal charge amount is read out to the column signal line 23. At this time, for example, by setting the voltage gain A of the negative feedback circuit 405 to 0, the first feedback line 24 is supplied with a first voltage. Also, a voltage gain B of the positive feedback circuit 406 at this time is 0. By bringing S1 to a Low level, the switch SW1 is connected to the constant voltage Vg. Thus, the power source line 25 is supplied with the power source voltage VDD.

At time t2, since the control signal Vres is turned on, the resetting of the pixel 10 is started. At this time, the voltage gain A of the negative feedback circuit 405 is set to be negative, and the voltage gain B of the positive feedback circuit 406 is set to be positive. Furthermore, by bringing S1 to a High level, the switch SW1 is connected to an output of the positive feedback circuit 406.

At time t3, because of the decrease in the control signal Vres, the reset transistor 117 is brought to a non-conductive state. Then, the voltage Vsig of the column signal line 23 starts decreasing. This is because, since the control signal Vres continues decreasing even after time t3, an output voltage of the amplification transistor 116 also decreases via the parasitic capacitance of the gate of the reset transistor 117 and the gate of the amplification transistor 116. Also, since the power source voltage VDD is controlled by the positive feedback circuit 406, the output voltage Vd to the power source line 25 varies. Then, the variation in the output voltage Vd to the power source line 25 propagates to the FD portion 115 via the gate-drain capacitance Cgd of the amplification transistor 116. At this time, if an absolute value of B is smaller than an absolute value of A, the above-noted propagation can be substantially ignored.

At time t4, the voltage Vsig of the column signal line 23 exceeds the input dynamic range of the negative feedback circuit 405, so that the voltage Vo of the first feedback line 24 becomes constant.

At time t5, the voltage Vsig of the column signal line 23 exceeds the input dynamic range of the positive feedback circuit 406, so that the voltage Vd of the power source line 25 becomes constant.

At time t6, the control signal Vres reaches the Low level. Immediately thereafter, the voltage Vsig corresponding to the kTC noise remaining in the FD portion 115 is superimposed and applied to the first feedback line 24 and the power source iine 25 via the column signal line 23. The polarity of the voltage Vo of the first feedback line 24 is opposite to the polarity of the voltage Vd of the power source line 25.

At time t7, similarly to time t1, by setting the voltage gain A of the negative feedback circuit 405 to 0, for example, the first feedback line 24 is supplied with the first voltage. Also, by bringing S1 to the Low level at this time, the switch SW1 is connected to the constant voltage Vg. Thus, the power source line 25 is supplied with the power source voltage VDD again. The standard deviation of the voltage variation of the power source line 25 at this time is expressed by Formula 5, similarly to Formula 2,

$$- B \sqrt{\frac{kT}{( A + 1 ) Cp}} \qquad [ Formula 5 ]$$

The negative sign corresponds to the fact that, unlike Formula 2, the voltage Vd of the power source line 25 that has varied this time takes an opposite sign to the voltage Vd before varying. This voltage variation is superimposed and applied to the FD portion 115 via Cgd. In other words, a total charge amount of the kTC noise is expressed by Formula 6.

$$( 1 + A \frac{Cfb}{Cp + Cfb} - B \frac{Cgd}{Cp + Cgd} ) \sqrt{\frac{kTCp}{( A + 1 )}} \qquad [ Formula 6 ]$$

By setting A and B so that Formula 6 produces zero, it is theoretically possible to bring the kTC noise to zero. Although the kTC noise cannot be brought to zero in reality owing to manufacturing variations or the like, it is possible to considerably reduce the kTC noise.

As described above, the solid-state imaging device according to the present embodiment includes the semiconductor substrate 118, and the pixel unit 12 including the plurality of pixels 10 that are disposed in a matrix on the substrate 118.

Each of the plurality of pixels 10 includes the photoelectric conversion film 108 that photoelectrically converts incident light to a signal charge, the lower electrode 111 that is disposed on the surface of the photoelectric conversion film 108 facing the substrate 118, the upper electrode 107 that is disposed on the surface of the photoelectric conversion film 108 opposite from the lower electrode 111, the FD portion 115 that is electrically connected to the lower electrode 111 and stores the signal charge, the amplification transistor 116 that outputs a pixel signal corresponding to the amount of the signal charge, the reset transistor 117 that resets a potential of the FD portion 115, and the selection transistor 202 that determines timing at which the amplification transistor 116 outputs the pixel signal.

For each column of the pixels, the pixel unit 12 includes the power source line 25 that is connected to one of the source and the drain of each of a plurality of the amplification transistors 116 disposed in the column, the column signal line 23 that is connected to one of the source and the drain of each of a plurality of the selection transistors 202 disposed in the column, the first feedback line 24 that is connected to one of the source and the drain of each of a plurality of the reset transistors 117 disposed in the column, the negative feedback circuit 405 having its input terminal connected to the column signal line 23 and its output terminal connected to the first feedback line 24, and the positive feedback circuit 406 having its input terminal connected to the column signal line 23. The negative feedback circuit 405 negatively feeds a signal outputted to the column signal line 23 back to the first feedback line 24, and the positive feedback circuit 406 positively feeds the signal outputted to the column signal line 23 back to the power source line 25.

Here, the charge amount of the kTC noise remaining in the FD portion 115 at the instant when the resetting is completed is defined by a sum of the standard deviation of the voltage variation of the power source line 25 and the standard deviation of the voltage variation of the first feedback line 24. With the above configuration, the standard deviation of the voltage variation of the power source line 25 and the standard deviation of the voltage variation of the first feedback line 24 are canceled out, thus making it possible to reduce the kTC noise.

Furthermore, the positive feedback circuit 406 and the second current source transistor 417 having its gate connectable to the output terminal of the positive feedback circuit 406 via the switch SW1, one of its source and drain connected to the power source line 25, and the other of its source and drain connected to the power source voltage VDD form the second amplification portion that positively feeds the signal outputted to the column signal line 23 back to the power source line 25. This makes it possible to connect the switch SW1 to the constant voltage Vg at the time of signal read-out (time t1 to time t2) and at the time of reset read-out (time t7 and thereafter), so that the power source line 25 is supplied with the power source voltage VDD. Consequently, it is possible to stably fix the potential of one of the source and the drain of the amplification transistor 116 at the time of read-out.

Moreover, the drive circuit included in the solid-state imaging device supplies a first voltage to the first feedback line 24 in a first period (time t1 to time t2) during which the pixel signal is read out to the column signal line 23, and supplies the first voltage to the first feedback line 24 in a second period (time t7 and thereafter) during which the potential of the FD portion 115 reset by the reset transistor 117 is read out to the column signal line 23. This makes it possible to stably reduce the kTC noise independently of the pixel signal. It should be noted that the above-noted drive circuit constitutes a drive unit including not only the row signal drive circuits 13a and 13b that output the control signal to be applied to the gate of the reset transistor 117 but also a drive circuit that outputs the control signal to be applied to the gate of the selection transistor 202 and the control signal S1 of the switch SW1.

### Embodiment 2

The following is a description of a solid-state imaging device according to Embodiment 2. A structural component substantially similar to that in Embodiment 1 may be assigned the same reference sign, and the description thereof will be omitted in some cases. Since the overall configuration and the sectional view of the solid-state imaging device according to Embodiment 2 are substantially similar to those of the solid-state imaging device according to Embodiment 1, the description thereof will be omitted here.

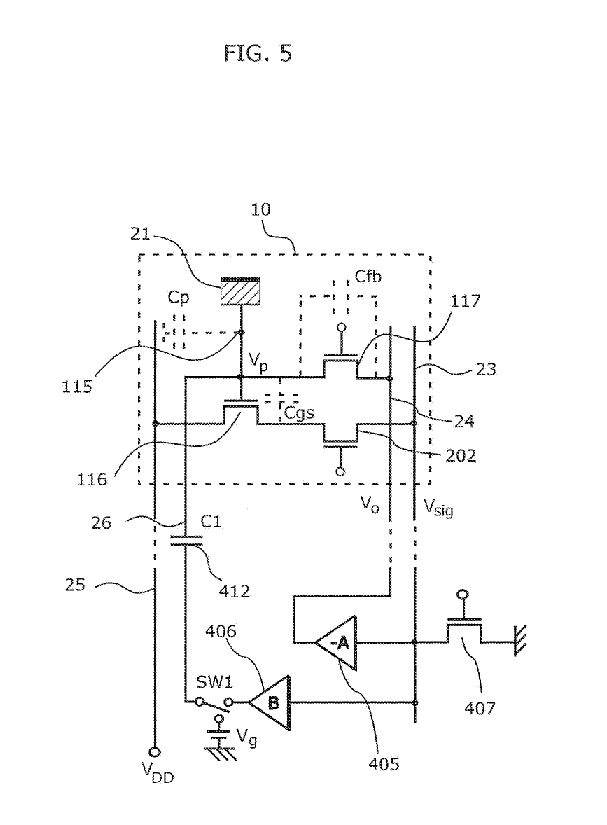

FIG. 5 is a circuit diagram illustrating a pixel and a control circuit in the solid-state imaging device according to Embodiment 2. More specifically, FIG. 5 illustrates an example of a circuit of the pixel 10 in the mth row and nth column in the pixel unit 12 and a control circuit thereof in the present embodiment, where m and n are natural numbers. Configurations that are different from the circuit of the pixel 10 and the control circuit thereof in Embodiment 1 will be mainly discussed.

Compared with the column-shared circuit according to Embodiment 1, a column-shared circuit according to Embodiment 2 further includes a feedback capacitor 412. One of terminals of the feedback capacitor 412 is connected to the output of the positive feedback circuit 406. The other of the terminals of the feedback capacitor 412 is connected to a second feedback line 26 that is connected to the gate of the amplification transistor 116. When the capacitance of the feedback capacitor 412 is given by C1, the total charge amount of the kTC noise is expressed by Formula 7 obtained by substituting C1 for Cgd in Formula 6,

$$( 1 + A \frac{Cfb}{Cp + Cfb} - B \frac{C 1}{Cp + C 1} ) \sqrt{\frac{kTCp}{( A + 1 )}} \qquad [ Formula 7 ]$$

By setting A and B so that Formula 7 produces zero, it is theoretically possible to bring the kTC noise to zero. Although the kTC noise cannot be brought to zero in reality owing to manufacturing variations or the like, it is possible to considerably reduce the kTC noise.

In Embodiment 1, the power source line 25 has had a function of supplying the power source voltage to the amplification transistor 116 and a function of positive feedback. In contrast, in Embodiment 2, the second feedback line 26 has the function of positive feedback. Also, Cgd is the parasitic capacitance in Embodiment 1, whereas the feedback capacitor 412 having the capacitance C1 is formed intentionally in Embodiment 2, making it possible to achieve a stable operation.

The method for driving the solid-state imaging device according to Embodiment 2 is the same as that for driving the solid-state imaging device according to Embodiment 1. In Embodiment 2, the variation in output of the positive feedback circuit 406 is superimposed and applied to the FD portion 115 via the feedback capacitor 412.

As described above, the solid-state imaging device according to the present embodiment includes the semiconductor substrate 118, and the pixel unit 12 including the plurality of pixels 10 disposed in a matrix on the substrate 118.

Each of the plurality of pixels 10 includes the photoelectric conversion film 108 that photoelectrically converts incident light to a signal charge, the lower electrode 111 that is disposed on the surface of the photoelectric conversion film 108 facing the substrate 118, the upper electrode 107 that is disposed on the surface of the photoelectric conversion film 108 opposite from the lower electrode 111, the FD portion 115 that is electrically connected to the lower electrode 111 and stores the signal charge, the amplification transistor 116 that outputs a pixel signal corresponding to the amount of the signal charge, the reset transistor 117 that resets an electric potential of the FD portion 115, and the selection transistor 202 that determines timing at which the amplification transistor 116 outputs the pixel signal.

For each column of the pixels, the pixel unit 12 includes the power source line 25 that is connected to one of the source and the drain of each of a plurality of the amplification transistors 116 disposed in the column, the column signal line 23 that is connected to one of the source and the drain of each of a plurality of the selection transistors 202 disposed in the column, the first feedback line 24 that is connected to one of the source and the drain of each of a plurality of the reset transistors 117 disposed in the column, the negative feedback circuit 405 having its input terminal connected to the column signal line 23 and its output terminal connected to the first feedback line 24, the positive feedback circuit 406 having its input terminal connected to the column signal line 23, the feedback capacitor 412 having one of its terminals connectable to the output terminal of the positive feedback circuit 406 via the switch SW1, and the second feedback line 26 having one end connected to the other of the terminals of the feedback capacitor 412 and the other end connected to the gate of each of the plurality of amplification transistors 116. The negative feedback circuit 405 negatively feeds a signal outputted to the column signal line 23 back to the first feedback line 24, and the positive feedback circuit 406 positively feeds the signal outputted to the column signal line 23 back to the second feedback line 26.

Here, the charge amount of the kTC noise remaining in the FD portion 115 at the instant when the resetting is completed is defined by the sum of the standard deviation of the voltage variation of the second feedback line 26 and the standard deviation of the voltage variation of the first feedback line 24. With the above configuration, the standard deviation of the voltage variation of the second feedback line 26 and the standard deviation of the voltage variation of the first feedback line 24 are canceled out, thus making it possible to reduce the kTC noise.

Moreover, the drive circuit included in the solid-state imaging device supplies the first voltage to the first feedback line 24 in the first period (time t1 to time t2) during which the pixel signal is read out to the column signal line 23, and supplies the first voltage to the first feedback line 24 in the second period (time t7 and thereafter) during which the potential of the FD portion 115 reset by the reset transistor 117 is read out to the column signal line 23. This makes it possible to stably reduce the kTC noise independently of the pixel signal. It should be noted that the above-noted drive circuit constitutes the drive unit including not only the row signal drive circuits 13a and 13b that output the control signal to be applied to the gate of the reset transistor 117 but also a drive circuit that outputs the control signal to be applied to the gate of the selection transistor 202 and the control signal S1 of the switch SW1.

Additionally, in the first period (time t1 to time t2) and the second period (time t7 and thereafter), the one terminal of the feedback capacitor 412 is connected to the constant voltage source Vg. Thus, it is possible to stably fix the potential of the second feedback line 26 at the time of read out.

Although the above description has been directed to the solid-state imaging devices according to the present disclosure based on Embodiments 1 and 2, the present disclosure is by no means limited to these embodiments. Many variations conceivable by a person skilled in the art without departing from the essence of the present disclosure also fall within the scope of the present disclosure. Moreover, individual structural components in a plurality of embodiments may be freely combined without departing from the purport of the present disclosure.

Furthermore, the solid-state imaging device according to the embodiments described above is typically implemented as an LSI, which is an integrated circuit. Such a solid-state imaging device may be individually made into a single chip or may be partially or entirely made into a single chip.

Additionally, ways to achieve circuit integration are not limited to the LSI, and a dedicated circuit or a general purpose processor can also achieve the integration. It may also be possible to utilize a field programmable gate array (FPGA) that can be programmed after the LSI production or a reconfigurable processor that can reconfigure the connection and settings of a circuit cell inside the LSI.

Moreover, in the sectional view, etc. illustrated above, a corner and a side of each structural component have been indicated linearly. However, the present disclosure also includes a corner and a side that are rounded due to manufacturing reasons.

The functions of the solid-state imaging device according to the embodiments described above may be at least partially combined.

Moreover, all of the numerals used above are examples for specifically describing the present disclosure, and the present disclosure is by no means limited to these numerals.

Although the above description has been directed to an example of using the MOS transistor, other transistors may also be used.

Furthermore, the present disclosure also includes many variations of the embodiments described above within the range conceivable by a person skilled in the art without departing from the purport of the present disclosure.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

### INDUSTRIAL APPLICABILITY

A solid-state imaging device according to the present disclosure is applicable to a digital still camera, a medical camera, a surveillance camera, a digital single-lens reflex camera, a digital mirrorless interchangeable lens camera or the like.

1. A solid-state imaging device comprising:
a semiconductor substrate; and
a pixel unit including a plurality of pixels that are disposed in a matrix on the semiconductor substrate,
wherein each of the plurality of pixels includes:
a photoelectric conversion film that photoelectrically converts incident light to a signal charge;
a pixel electrode that is disposed on a semiconductor substrate-side surface of the photoelectric conversion film;
a transparent electrode that is disposed on a surface of the photoelectric conversion film, the surface of the photoelectric conversion film being opposite from the pixel electrode;
a charge storage portion that is electrically connected to the pixel electrode and stores the signal charge;
an amplification transistor that outputs a pixel signal corresponding to an amount of the signal charge;
a reset transistor that resets an electric potential of the charge storage portion; and
a selection transistor that determines timing at which the amplification transistor outputs the pixel signal,
for each column of the plurality of pixels, the pixel unit includes:
a power source line that is connected to one of a source and a drain of each of a plurality of the amplification transistors disposed in the each column;
a column signal line that is connected to one of a source and a drain of each of a plurality of the selection transistors disposed in the each column;
a first feedback line that is connected to one of a source and a drain of each of a plurality of the reset transistors disposed in the each column;
a first amplification portion including an input terminal connected to the column signal line and an output terminal connected to the first feedback line; and
a second amplification portion including an input terminal connected to the column signal line,
the first amplification portion negatively feeds a signal outputted to the column signal line back to the first feedback line, and
the second amplification portion positively feeds the signal outputted to the column signal line back to the power source line.

2. The solid-state imaging device according to claim 1,
wherein the second amplification portion includes:
an amplification circuit that includes an input terminal connected to the column signal line and has a negative gain; and
a MOS transistor that includes a gate, a source and a drain, the gate being connectable to an output terminal of the amplification circuit via a switch, one of the source and the drain being connected to the power source line, and the other of the source and the drain being connected to a power source.

3. The solid-state imaging device according to claim 1, further comprising
a drive unit that supplies a first voltage to the first feedback line in a first period during which the pixel signal is read out to the column signal line, and supplies the first voltage to the first feedback line in a second period during which the electric potential of the charge storage portion reset by the reset transistor is read out to the column signal line.

4. A solid-state imaging device according to claim 3,
wherein the second amplification portion includes:
an amplification circuit that includes an input terminal connected to the column signal line and has a negative gain; and
a MOS transistor that includes a gate, a source and a drain, the gate being connectable to an output terminal of the amplification circuit via a switch, one of the source and the drain being connected to the power source line, and the other of the source and the drain being connected to a power source, and
in the first period and the second period, the source and the drain of the MOS transistor are in a conducting state.

5. A solid-state imaging device comprising:
a semiconductor substrate; and
a pixel unit including a plurality of pixels that are disposed in a matrix on the semiconductor substrate,
wherein each of the plurality of pixels includes:
a photoelectric conversion film that photoelectrically converts incident light to a signal charge;
a pixel electrode that is disposed on a semiconductor substrate-side surface of the photoelectric conversion film;
a transparent electrode that is disposed on a surface of the photoelectric conversion film, the surface of the photoelectric conversion film being opposite from the pixel electrode;
a charge storage portion that is electrically connected to the pixel electrode and stores the signal charge;
an amplification transistor that outputs a pixel signal corresponding to an amount of the signal charge;
a reset transistor that resets an electric potential of the charge storage portion; and
a selection transistor that determines timing at which the amplification transistor outputs the pixel signal,
for each column of the plurality of pixels, the pixel unit includes:
a power source line that is connected to one of a source and a drain of each of a plurality of the amplification transistors disposed in the each column;
a column signal line that is connected to one of a source and a drain of each of a plurality of the selection transistors disposed in the each column;
a first feedback line that is connected to one of a source and a drain of each of a plurality of the reset transistors disposed in the each column;
a first amplification portion including an input terminal connected to the column signal line and an output terminal connected to the first feedback line;
a second amplification portion including an input terminal connected to the column signal line;
a feedback capacitor including terminals, one of the terminals being connectable to an output terminal of the second amplification portion via a switch; and
a second feedback line including one end connected to the other of the terminals of the feedback capacitor and the other end connected to a gate of each of the plurality of the amplification transistors,
the first amplification portion negatively feeds a signal outputted to the column signal line back to the first feedback line, and
the second amplification portion positively feeds the signal outputted to the column signal line back to the second feedback line.

6. A solid-state imaging device according to claim 5, further comprising
a drive unit that supplies a first voltage to the first feedback line in a first period during which the pixel signal is read out to the column signal line, and supplies the first voltage to the first feedback line in a second period during which the electric potential of the charge storage portion reset by the reset transistor is read out to the column signal line.

7. A solid-state imaging device according to claim 6,
wherein in the first period and the second period, the one of the terminals of the feedback capacitor is connected to a constant voltage source.
